(19) United States
(12) Patent Application Publication
(10) Pub. No.: US 2012/0167957 A1
(43) Pub. Date: Jul. 5, 2012

(54) SOLAR PANEL INSTALLATION SYSTEMS AND METHODS

(75) Inventors: Neal R. Verfuerth, Manitowoc, WI (US); Tony Freeman, DePere, WI (US); Jason Rasner, DePere, WI (US)

(73) Assignee: Orion Energy Systems, Inc.

(21) Appl. No.: 13/333,293

(22) Filed: Dec. 21, 2011

Related U.S. Application Data
(60) Provisional application No. 61/429,349, filed on Jan. 3, 2011.

(51) Int. Cl. H01L 31/048; H01L 31/18

(52) U.S. Cl. 136/251; 29/890.033

(57) ABSTRACT

A system for installing a preassembled array of solar panels on a rooftop of a facility includes a primary beam member having a plurality of transverse receptacles, a plurality of transverse rails engaged with the transverse receptacles, and a plurality of panel supports, each having a hook portion, and movably supported by the transverse rails, so that each corner of the solar panels in the preassembled array is supported by at least one panel support. A system for transporting solar panels to a rooftop of a facility for subsequent assembly into an array includes a high density rack having a plurality of parallel tracks, each of the parallel tracks are arranged in a progressively staggered configuration, so that one of the solar panels is receivable on each of the parallel tracks, with one side of each of the solar panels having at least one downwardly extending standoff coupled thereto.

### CROSS-REFERENCE TO RELATED APPLICATIONS

This patent application claims the benefit of priority under 35 U.S.C. §119(e) of U.S. Provisional Application No. 61/429,349, having a filing date of Jan. 3, 2011, titled “Solar Panel Installation Systems and Methods,” the complete disclosure of which is hereby incorporated by reference in its entirety.

### FIELD

The present disclosure relates generally to the field of systems and methods for installing solar panels. More specifically, the present disclosure relates to systems and methods for installing photovoltaic solar panels on a surface (e.g. rooftop, etc.) of a facility. Still more specifically, the present disclosure relates to a first system and method for installing solar panels in a preassembled array configuration on a rooftop, and a second system and method for transporting the solar panels to the rooftop for subsequent assembly into an array configuration. More specifically still, a system and method for minimally-invasive installation of solar panels on a rooftop of a facility is disclosed that includes the steps of assembling a plurality of solar panels into a preassembled array at a first location separate from the rooftop, mechanically and electrically interconnecting the solar panels in the array at the first location, coupling a lifting apparatus to the preassembled array, aerially transporting the preassembled array from the first location to a second location disposed on the rooftop, and electrically connecting the preassembled array to an electrical circuit for the facility.

### BACKGROUND

This section is intended to provide a background or context to the subject matter recited in the claims. The description herein may include concepts that could be pursued, but are not necessarily ones that have been previously conceived or pursued. Therefore, unless otherwise indicated herein, what is described in this section is not prior art to the description and claims in this application and is not admitted to be prior art by inclusion in this section.

It is well known to provide solar panels such as photovoltaic panels for placement upon the rooftop of a facility, and then interconnecting them into an array to provide a desired capacity of electrical energy from a renewable power source (e.g. the sun). However, the conventional systems and methods for installing such solar panels on rooftops tend to be tedious and time-consuming, and thus expensive, which tends to make solar panel installations unnecessarily, and sometimes prohibitively, expensive.

Accordingly, it would be desirable to provide one or more systems and methods for installation of photovoltaic solar panels that overcomes these and other disadvantages.

### SUMMARY

One embodiment of the disclosure relates to a system for installing a preassembled array of solar panels on a rooftop of a facility. The system includes a primary beam member having a plurality of transverse receptacles and a plurality of transverse rails engaged with the transverse receptacles. A plurality of panel supports, each having a hook portion, are movably supported by the transverse rails, so that each of the solar panels in the preassembled array is supported by at least one of the panel supports.

Another embodiment of the disclosure relates to a system for transporting a plurality of solar panels to a rooftop of a facility for subsequent assembly into an array. The system includes a high-density rack having one or more pairs of staggered track groups, each pair of staggered track groups having a plurality of parallel tracks, and each of the parallel tracks arranged in a progressively staggered configuration, so that one of the solar panels is receivable on each of the parallel tracks, and one side of the solar panels is capable of having at least one downwardly extending standoff coupled thereto.

Another embodiment of the disclosure relates to a method of installing an array of solar panels on a rooftop of a facility. The method includes the steps of providing a primary beam member having a plurality of transverse receptacles, coupling a plurality of transverse rails to the transverse receptacles, movably supporting a plurality of panel supports having a hook portion from the transverse rails, engaging the hook portion of the panel supports with the solar panels in the preassembled array, and lifting the preassembled array of solar panels and positioning the array onto the rooftop at a location proximate a perimeter of the facility.

Another embodiment of the disclosure relates to a method of transporting solar panels to a rooftop of a facility for subsequent assembly into an array. The method includes the steps of providing a first rack having a plurality of parallel tracks, each of the parallel tracks arranged in a progressively staggered configuration, so that at least one of the solar panels is receivable on each of the parallel tracks, and loading a first supply of the solar panels onto the parallel tracks, and coupling at least one downwardly extending standoff on one side of each of the solar panels, and lifting the first rack and positioning the rack onto the rooftop, and unloading the first supply of the solar panels from the first rack, and assembling the solar panels into an array at an inwardly-disposed location on the rooftop.

Another embodiment of the disclosure relates to a method of installing solar panels on a rooftop of a facility. The method includes the steps of installing a first group of solar panels that have been preassembled into a first array on a rooftop proximate a peripheral location according to the following sub-steps: providing a primary beam member having a plurality of transverse receptacles, and coupling a plurality of transverse rails to the transverse receptacles, and movably supporting a plurality of panel supports having a hook portion from the transverse rails, and engaging the hook portion of the panel supports with the solar panels in the preassembled array, and lifting the preassembled array of solar panels and positioning the array onto the rooftop at a location proximate a perimeter of the facility. The method also includes the steps of transporting a second group of solar panels to an inward location on the rooftop that is inwardly disposed from the peripheral location, and assembling the second group of solar panels into a second array, according to the following sub-steps: providing a rack having a plurality of parallel tracks, each of the parallel tracks arranged in a progressively staggered configuration, so that at least one of the solar panels is receivable on each of the parallel tracks, coupling at least one downwardly extending standoff on one side of each of the solar panels, and lifting the rack and positioning the rack onto the rooftop, removing the solar panels from the rack, and assembling the solar panels into an array at the inward location on the rooftop.

Another embodiment of the disclosure relates to a method for minimally-invasive installation of solar panels on a rooftop of a facility. The method includes the steps of assembling a plurality of solar panels into a preassembled array at a first location separate from the rooftop, mechanically and electrically interconnecting the solar panels in the array at the first location, coupling a lifting apparatus to the preassembled array, aerially transporting the preassembled array from the first location to a second location disposed on the rooftop, and electrically connecting the preassembled array to an electrical circuit for the facility

### BRIEF DESCRIPTION OF THE DRAWINGS

The disclosure will become more fully understood from the following detailed description, taken in conjunction with the accompanying figures, wherein like reference numerals refer to like elements, in which:

FIG. 1 is a schematic representation of an isometric view of a rooftop of a facility having multiple arrays of photovoltaic solar panels installed according to the exemplary systems and methods described herein.

FIG. 2 is a schematic representation of a partial isometric view of a first system for installing a preassembled array of solar panels on a rooftop of a facility, according to an exemplary embodiment.

FIG. 3 is a schematic representation of another partial isometric view of the first system for installing a preassembled array of solar panels on a rooftop of a facility, according to an exemplary embodiment.

FIG. 4 is a schematic representation of a full isometric view of the first system for installing a preassembled array of solar panels on a rooftop of a facility, according to an exemplary embodiment.

FIG. 5 is a schematic representation of a full isometric view of a deployment of the first system for installing a preassembled array of solar panels on a rooftop of a facility, according to an exemplary embodiment.

FIG. 6 is a schematic representation of a front perspective view of a second system for transporting solar panels to a rooftop of a facility for subsequent assembly into an array, according to an exemplary embodiment.

FIG. 7 is a schematic representation of a rear isometric view of the second system for transporting solar panels to a rooftop of a facility for subsequent assembly into an array, according to an exemplary embodiment.

FIG. 8 is a schematic representation of a front perspective view of the second system for transporting solar panels to a rooftop of a facility for subsequent assembly into an array, in a loaded configuration, according to an exemplary embodiment.

FIG. 9 is a schematic representation of a rear isometric view of the second system for transporting solar panels to a rooftop of a facility for subsequent assembly into an array, in a loaded configuration, according to an exemplary embodiment.

FIG. 10 is a schematic representation of a perspective view of a lifting rig for the second system for transporting solar panels to a rooftop of a facility for subsequent assembly into an array, according to an exemplary embodiment.

FIG. 11 is a schematic representation of a perspective view of the lifting rig with the second system for transporting solar panels to a rooftop of a facility for subsequent assembly into an array, according to an exemplary embodiment.

FIG. 12 is a schematic representation of a detailed partial isometric view of two adjacent solar panels connected to one another by a connector for assembly of the panels into an array, according to an exemplary embodiment.

FIG. 13 is a schematic representation of a detailed isometric view of the connector of FIG. 12 for connecting the solar panels into an array, according to an exemplary embodiment.

### DETAILED DESCRIPTION

Referring to the FIGURES a first system and method for installing solar panels in a preassembled array configuration on a rooftop (typically along perimeter locations on the rooftop), and a second system and method for transporting the solar panels to the rooftop (typically more inwardly-disposed locations on the rooftop) for subsequent assembly into an array configuration on the rooftop, are shown according to exemplary embodiments. Together, the first and second system and method or intended to provide a fast, convenient, efficient, and thus lower cost system and method for installing solar panels in any desired pattern and at any desired location on the rooftop of a facility.

According to one embodiment of the disclosure, in the first system and method for installing solar panels in a preassembled array configuration on a rooftop of a facility, the solar panels are preassembled by mechanically and electrically interconnecting them to form the array at a location that is conveniently accessible to workers and nearby the rooftop installation location. The array may comprise any number and configuration of interconnected solar panels, such as an X by Y (e.g. column by row) matrix configuration, as may be desired to accommodate the spatial area at the rooftop location, avoid existing structures or equipment on the rooftop, and provide the desired electrical capacity. The solar panels are delivered to the assembly area and then prepared for assembly into the array by connecting standoffs (e.g. feet, etc.) that are configured to support the panels at a predefined elevation above the rooftop. The array is mechanically assembled by connecting adjacent solar panels to one another by quick-install connectors, such as snap-fit spring clips. The array is electrically assembled by coupling electrical connectors from each panel into a desired circuit arrangement for the array.

Once the solar panels are preassembled into the desired array, a universal lifting apparatus is provided for use in lifting the preassembled array onto the rooftop. The universal lifting apparatus of the first system and method includes a primary beam member that may be connected to the crane using suitable slings, etc. The primary beam member is shown as formed from tubular steel, and may be configured to receive one or more secondary beam members at one or both ends of the primary beam member in order to extend the reach of the primary beam member to span any desired length of the preassembled array. The primary and secondary beam members include transverse receptacles configured to receive transverse rails spaced along the length of the beam(s) at a distance generally corresponding to the width of the solar panels. The rails may have any suitable length (or be provided in multiple or adjustable lengths) to span the width of the array. The number of rails installed on the beam(s) is intended to correspond to the number of columns of solar panels, plus one. A plurality of panel supports are adjustably disposed along the rails at locations corresponding generally to the ends of the panels, and having a hook portion configured to receive both a single border frame at the outer sides of the array of solar panels, and the double (i.e. connected) frames interior to the array of solar panels. The panel supports are intended to be quickly and conveniently installed and adjusted along the rails. The panel supports are configured to support all corners of the solar panels, so that when the beam(s) are lifted by the crane, all the panels in the array are uniformly supported and lifted by the rails and panel supports connected thereto.

According to another embodiment of the disclosure, in the second system and method for transporting the solar panels to a rooftop of a facility for subsequent assembly into an array configuration, the second system and method includes a rack having a plurality of groups of staggered tracks, where each track is configured to receive a solar panel. The staggered configuration of the tracks permits the pre-placement of standoffs on one side of the solar panels, and on the opposite side of the bottom solar panel in each group. The rack further includes a lifting apparatus that is quickly coupled to a top portion of the rack, and includes a lift-eye for lifting the rack using a suitable lifting device such as a crane. According to one embodiment, at least two racks are used during installation activities so that one rack may be on the ground to facilitate loading of new solar panels onto the groups of staggered tracks by a ground work crew, while another loaded rack may be transported by the crane to the rooftop for unloading and installation by a rooftop work crew. The lifting apparatus includes suitable latches that engage corresponding structure on the top portion of the racks to permit rotation of the racks between ground and rooftop operations.

Both the first and second systems and methods for installing a solar panel array on a rooftop of a facility are intended to have a number of advantages over conventional systems and methods. For example, most conventional solar panel systems require fasteners that penetrate or pierce the rooftop membrane or material in order to secure the panels in position on the rooftop, which tends to require increased labor steps and significantly raises the risk of subsequent leakage through the rooftop; the repair of which is much more complicated due to the presence of solar panels that have been fastened to the rooftop. The systems and methods of the present embodiments provide panel support structures that are deployable on the rooftop without the need for fastening to the rooftop, thus practically eliminating the risk of leak development typically associated with the fastening of conventional solar panel systems to a rooftop.

The first and second systems for installing a solar panel array on a rooftop of a facility as described herein also significantly reduce and minimize the amount of worker traffic (e.g. walking back-and-fort, climbing, etc.) and related incidents (e.g. dropping tools, fasteners, etc.) on the rooftop that are usually associated with the placement and the mechanical/electrical connections of the solar panels, because the panels are mechanically and electrically interconnected on the ground and then transported by an aerial lift in a preassembled manner to their placement location on the rooftop. Once the panels are positioned on the rooftop (e.g. by a suitable crane or the like), worker access is intended to be minimal (e.g. one final electrical hookup of the entire preassembled array, etc.). Such improved systems and methods for deploying an array of solar panels on a rooftop more readily permit the facility owner to install solar panels and obtain the benefits of electrical power generation from a renewable energy source without voiding any warranties that may be associated with the rooftop structure or materials of the facility. Further, in the event that subsequent access to the rooftop for other issues or maintenance is necessary, the panels may be readily lifted (e.g. temporarily) from the rooftop using the systems and methods described herein and then repositioned when such other roof work or tasks have been completed. Accordingly, the systems and methods for installing an array of solar panels on the rooftop of a facility as described herein are intended to provide a number of significant advantages over conventional solar panel placement and assembly methods.

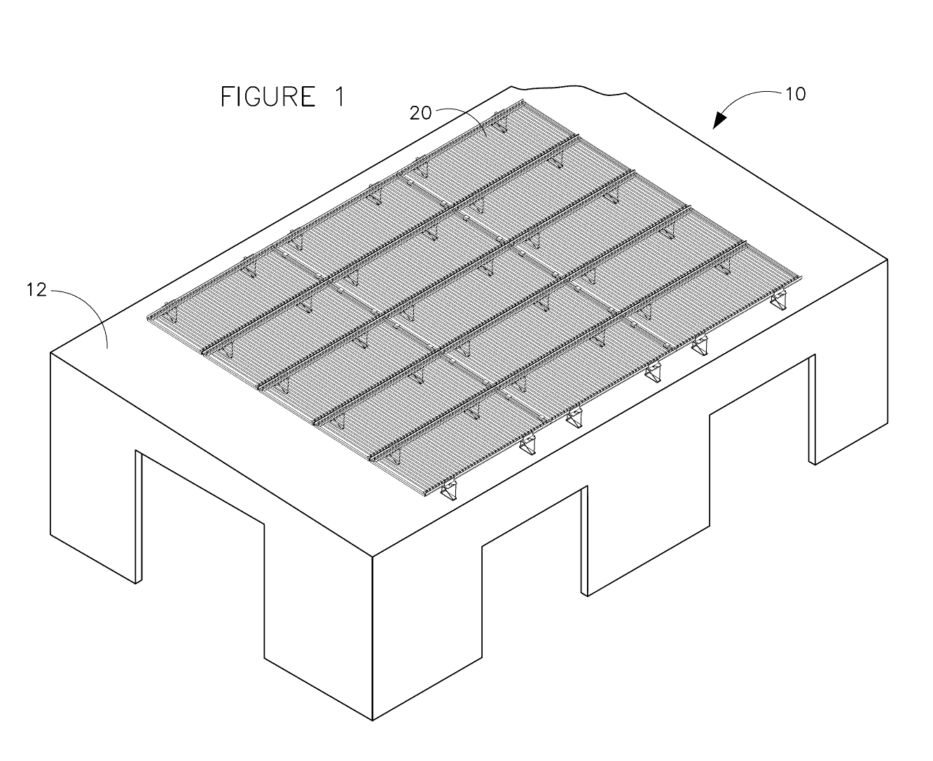

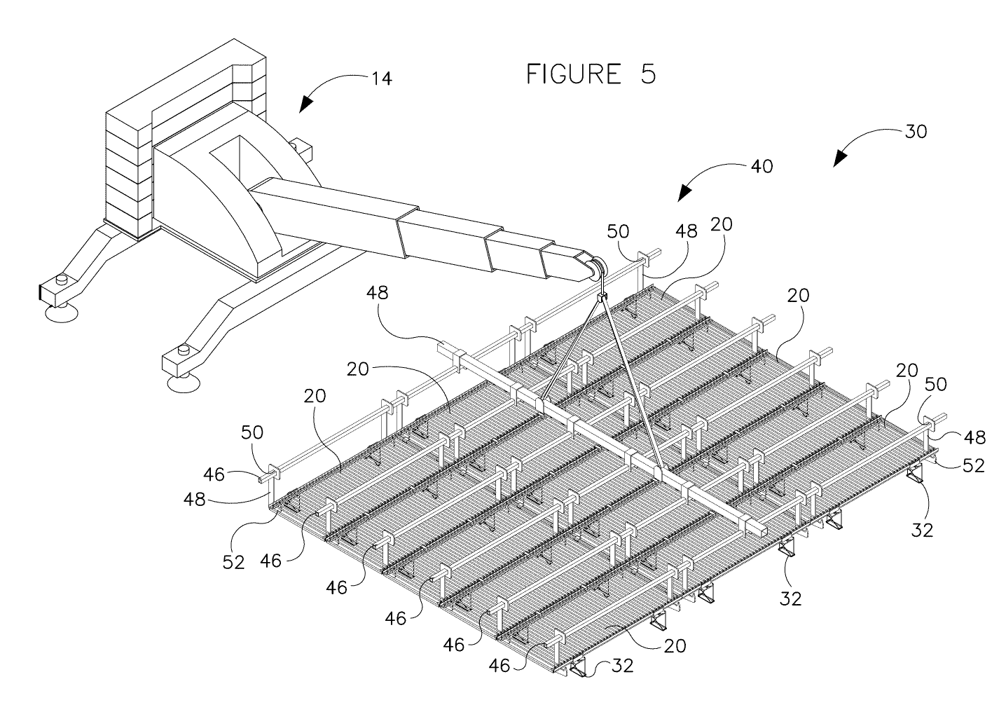

Referring more particularly to FIG. 1, an installation location 10 for arrays of solar panels 20 is shown by way of example to include a surface (shown as a substantially flat rooftop surface 12) of a facility. The rooftop 12 includes areas that are generally disposed near a perimeter of the facility and are advantageously suited for use with the first system and method of installing preassembled arrays of solar panels at locations that are within the reach of a lifting device such as a crane 14 (as shown by way of example in FIG. 5), and areas that are more inwardly-disposed (i.e. away from the perimeter of the facility) that are more advantageously suited for servicing with the second system and method for installing solar panels for subsequent positioning and assembly into an array on the rooftop 12. Using either system and method, wiring from the arrays of solar panels 20 to the electrical system for the facility may be provided in one or more raceway trays having easily removable covers, in order to minimize or eliminate the need to install hard conduit and pull the wiring through the conduits on the rooftop. According to one embodiment, either system may be configured as a mobile set of equipment configured to be readily transported from one jobsite to another to facilitate fast and cost-effective installation of solar panels at a facility. The mobile set of equipment may include a road transportable crane, tractor trailers carrying a generator, and all terrain fork lift, rigging and assembly/installation tools. All such embodiments are intended to be within the scope of this disclosure.

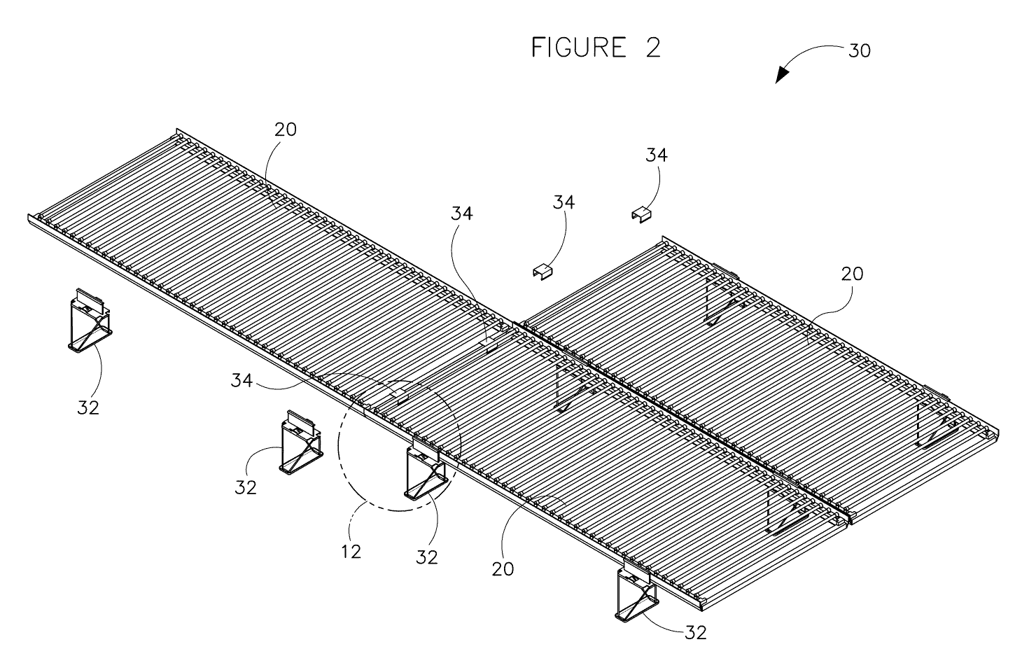

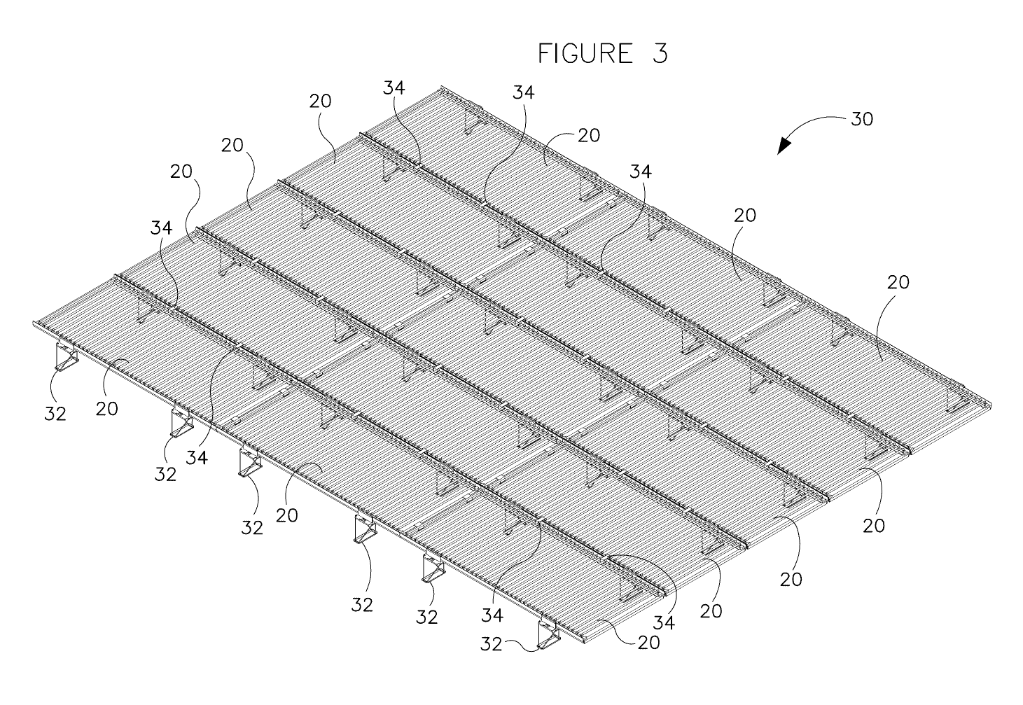

Referring more particularly to FIGS. 2-5, a first system and method 30 for installing solar panels 20 in a preassembled array configuration on a rooftop 12 of a facility is shown according to an exemplary embodiment. The solar panels 20 may be any suitable type of solar panel, such as (but not limited to) a photovoltaic solar panel having cylindrical PV modules and commercially available from Solyndra, Inc. of Freemont, Calif., and are preassembled by mechanically and electrically interconnecting them to form the array at a location that is conveniently accessible to workers and nearby the rooftop installation location 10 (e.g. at a staging area on the ground adjacent to the facility, etc.). The array may comprise any number and configuration of interconnected solar panels 20, such as an X by Y (e.g. column by row) matrix configuration, as may be desired to accommodate the spatial area at the rooftop 12 location, avoid existing structures or equipment on the rooftop 12, and provide the desired electrical capacity.

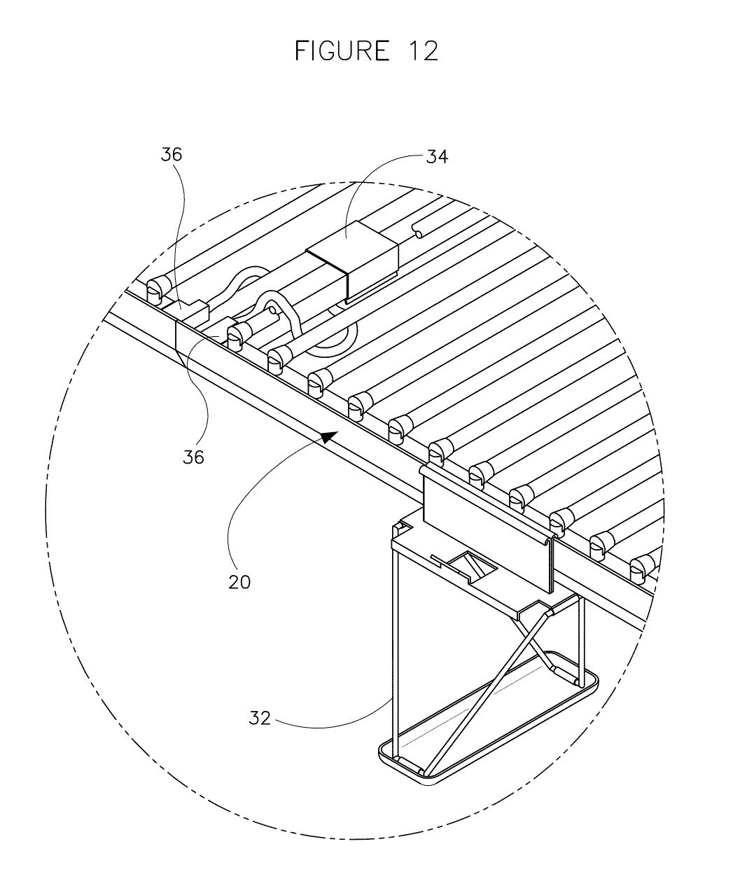

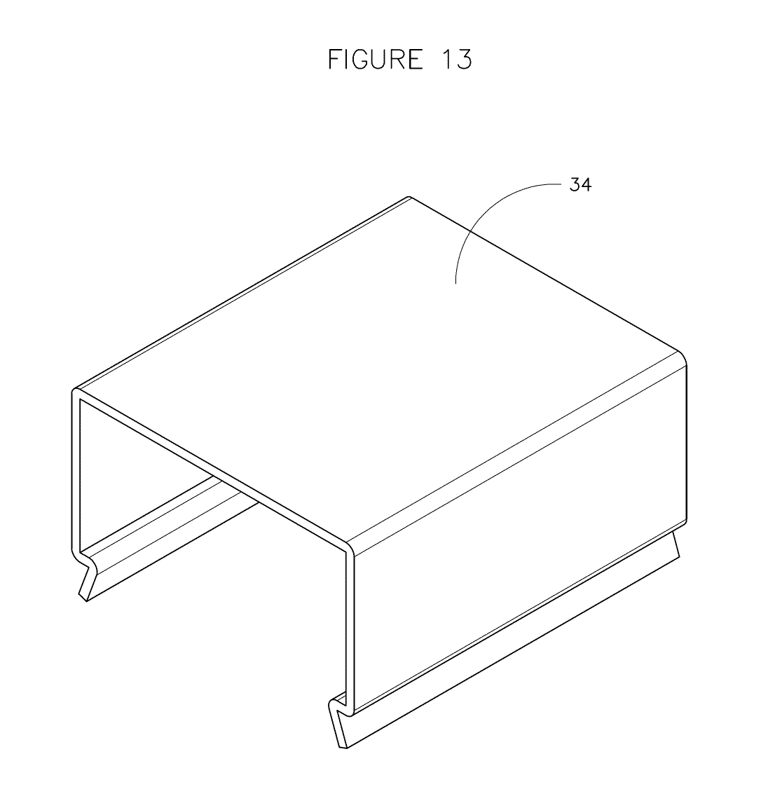

The solar panels 20 are delivered to the staging area and then prepared for assembly into the array by connecting (e.g. in a slide-lock, snap-fit or interference-fit manner, etc.) standoffs 32 (e.g. feet, etc.) that are configured to support the panels 20 at a predefined elevation above the rooftop 12 (e.g. to facilitate collection of solar energy on the underside of the solar panel by light that is reflected from the surface of the rooftop). The standoffs 32 may be configured to elevate the solar panels 20 at any particular height above the rooftop 12 surface, as may be advantageous (or required) to comply with certain building codes (e.g. seismic factors, etc.) or to avoid being covered by snow, etc. According to one embodiment, the array is mechanically assembled by connecting adjacent solar panels to one another with quick-install connectors 34, such as snap-fit spring clips (shown by way of example in FIGS. 12-13). The array is electrically assembled by coupling electrical connectors 36 (shown by way of example in FIG. 12) from each panel 20 into a desired circuit arrangement for the array.

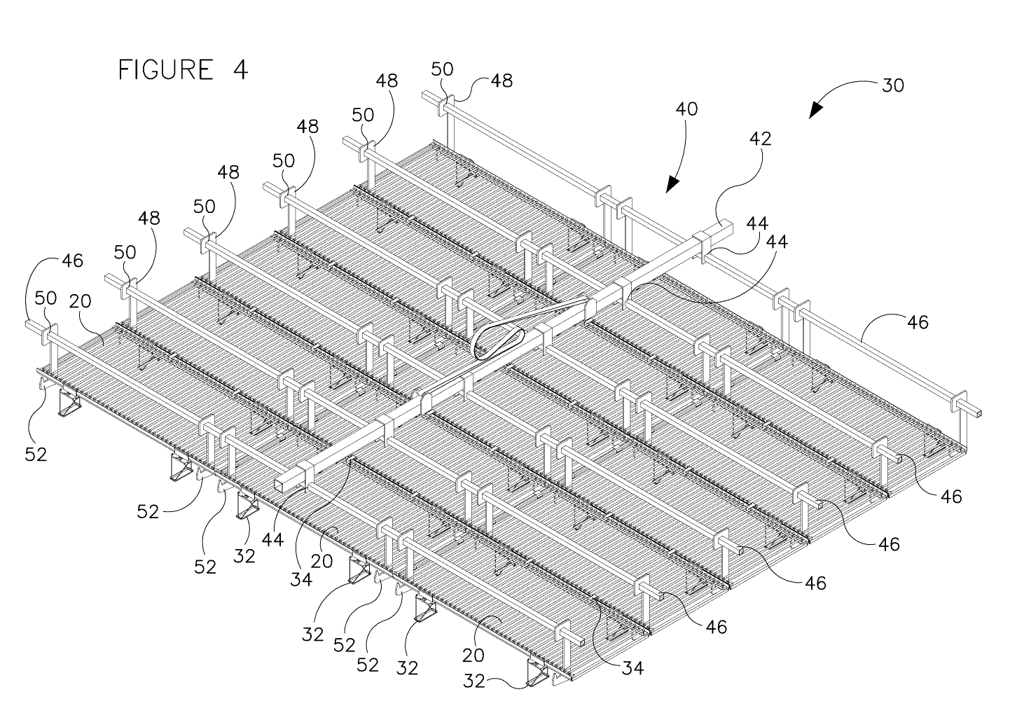

Referring further to FIGS. 4-5, once the solar panels 20 are preassembled into the desired array, a universal lifting apparatus 40 is provided for use in lifting (e.g. with a crane 14 or other suitable lifting device) the preassembled array from the staging area and onto the rooftop 12. The universal lifting apparatus 40 of the first system and method 30 includes a primary beam member 42 (e.g. strong-back, etc.) that may be connected to the crane 14 using suitable slings, etc. The primary beam member 42 is shown by way of example as formed from tubular steel, and may be configured to receive (e.g. in a telescoping, or “tent-pole,” or other suitable manner) one or more secondary beam members (e.g. extensions—not shown) at one or both ends of the primary beam member in order to extend the reach of the primary beam member to span any desired length (i.e. number of columns) of the preassembled array.

Referring further to FIGS. 4-5, the primary beam members 42 (and any secondary beam members) are shown to include transverse receptacles 44 configured to receive transverse rails 46 spaced along the length of the primary beam(s) 42 at a distance substantially corresponding to the width of the solar panels 29. The transverse receptacles 44 may be formed directly in (e.g. through) the beams, or may project outwardly from the beam(s). The transverse rails 46 may have any suitable length (or be provided in multiple or adjustable lengths) to span the width (i.e. the number of rows) of the array. The number of rails 46 installed on the beam(s) is intended to correspond to the number of columns of solar panels, plus one (i.e. so that the rails 46 provide support to the side frames of each solar panel 20 in the array).

A plurality of panel supports 48 are provided to interface between the rails 46 and the solar panels 20, and have a first end 50 that is adjustably (e.g. slideably, etc.) disposed along the rails 46 at locations corresponding generally to the ends of the panels 20. The panel supports 48 have a second end with a hook portion 52 configured to receive both a single border frame (e.g. at the outer sides of the array of solar panels 20), and double (i.e. connected) border frames within the array of solar panels. The panel supports 48 are intended to be quickly and conveniently installed and adjusted along the rails 46, such as, by way of example, having an eye portion through which the rail 16 extends in a slip-fit manner. According to the illustrated embodiment, the panel supports 48 are disposed in a manner configured to support all corners of the solar panels 20 in the array, so that when the beam(s) 42 are lifted by the crane 14, all the panels 20 in the array are substantially uniformly supported and lifted by the rails 46 and panel supports 48 connected thereto.

According to one embodiment, the primary beam member 42 and the transverse rails 46 and the panel supports 48 are assembled into a substantially symmetric and balanced arrangement to define the lifting apparatus 40, which is configured to transport the solar panels 20 to a peripheral location on the rooftop 12. The lifting apparatus 40 is intended to be uniformly adaptable to an array having any size by adjusting the length of the beam(s) 42 and the number and/or length of the rails 46, and the number and location of panel supports 48. One example of a situation where the first system and method of installing solar panels tends to be particularly advantageous is for placement of arrays along a perimeter portion of the rooftop 12 where the ‘reach’ of the crane 14 is sufficient to place the array in the desired location. When the desired rooftop location is beyond the reach of the crane 14 for placing a preassembled array of solar panels 20 thereon, a second system and method 60 becomes advantageous for transporting solar panels 20 to the rooftop 12 for subsequent placement and assembly of the solar panels 20 into the desired array.

According to one embodiment of the disclosure, the first method 30 of installing a preassembled array of solar panels 20 on a rooftop 12 of a facility includes (among possible others) the steps of: providing a primary beam member 42 having a plurality of transverse receptacles 44; coupling a plurality of transverse rails 46 to the transverse receptacles 44; movably supporting a plurality of panel supports 48 having a hook portion 52 from the transverse rails 46; engaging the hook portion 52 of the panel supports 48 with each corner of the solar panels 20 in the preassembled array; and lifting the preassembled array of solar panels 20 and positioning the array onto the rooftop 12 at a location proximate a perimeter of the facility.

According to another embodiment of the disclosure, the first method 30 of minimally-invasive installation of solar panels 20 on a rooftop 12 of a facility includes (among possible others) the steps of: assembling a plurality of solar panels 20 into a preassembled array at a first location separate from the rooftop 12; mechanically and electrically interconnecting the solar panels 20 in the array at the first location; coupling a lifting apparatus 40 to the preassembled array; aerially transporting the preassembled array from the first location to a second location disposed on the rooftop 12; and electrically connecting the preassembled array to an electrical circuit for the facility.

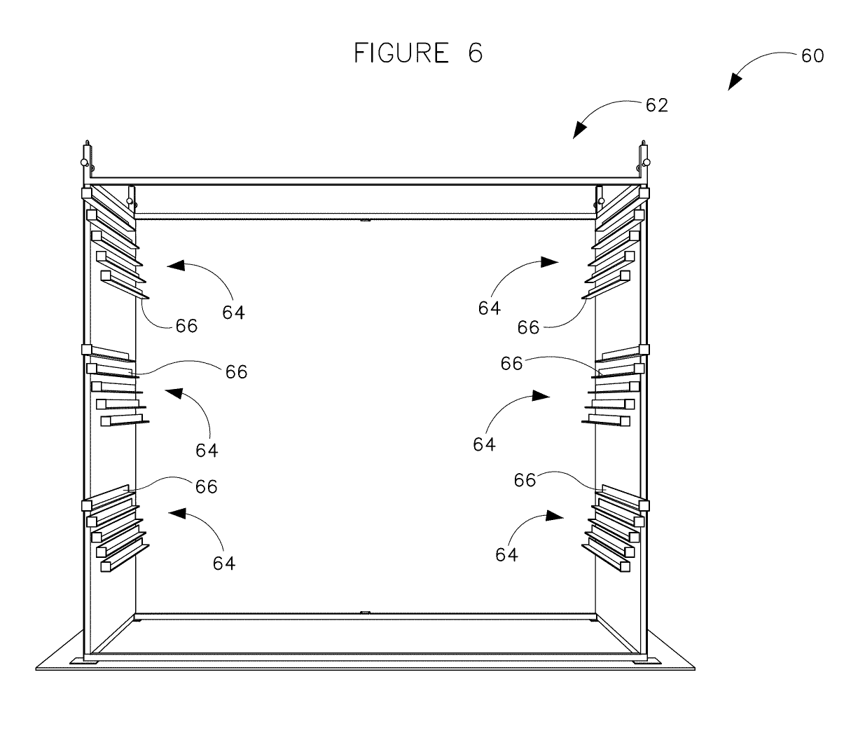

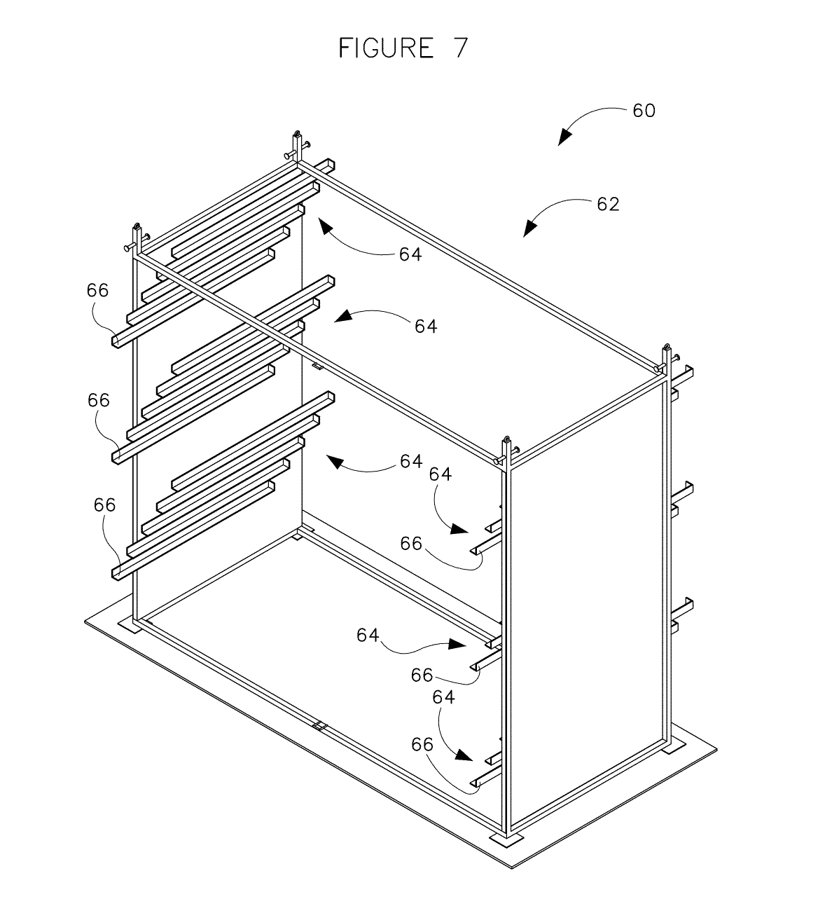

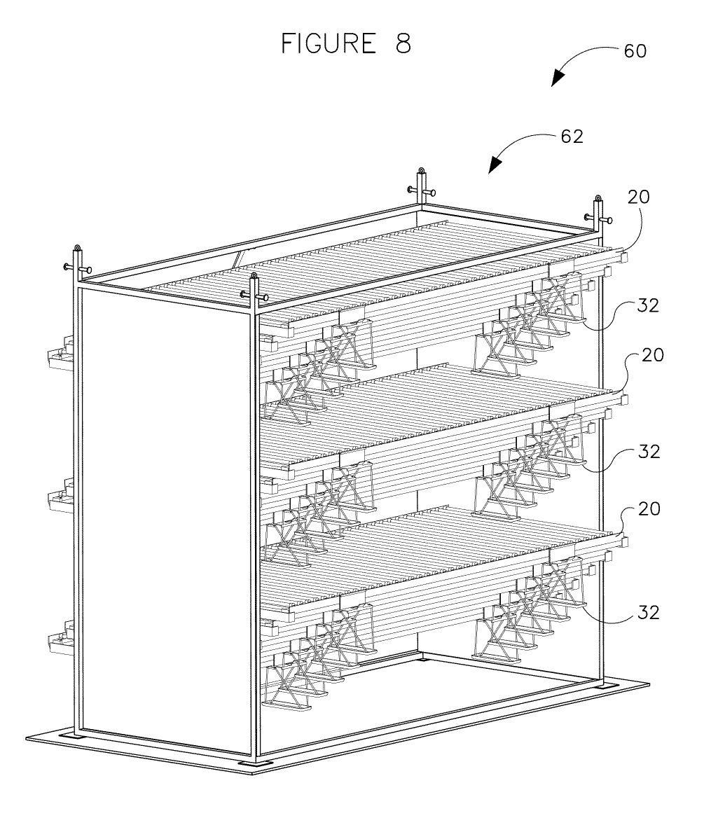

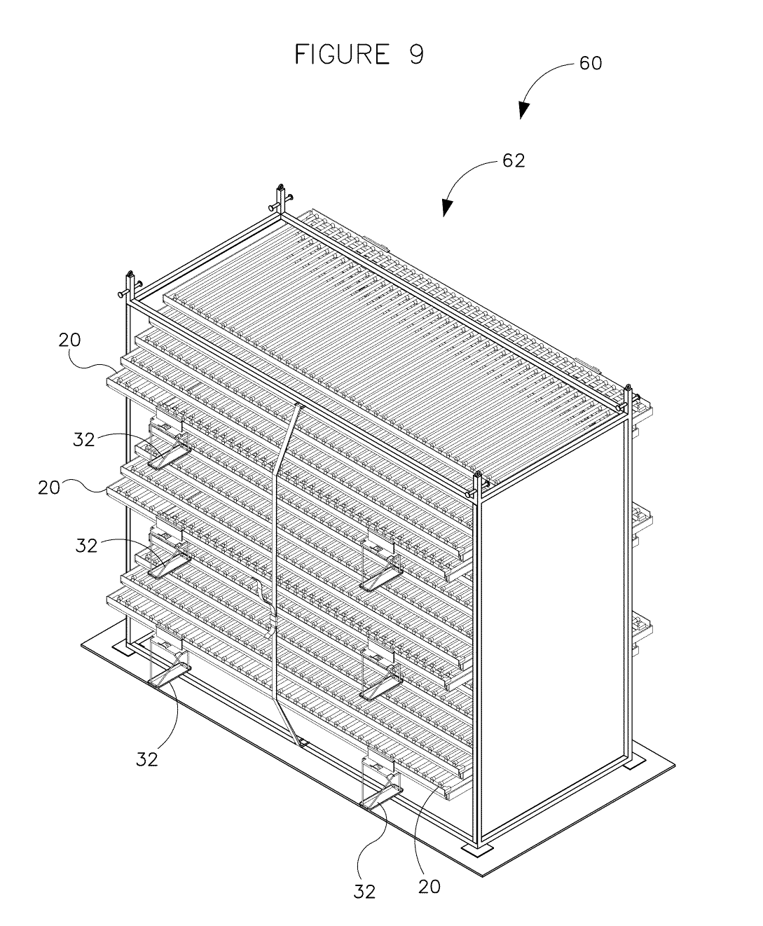

Referring more particularly to FIGS. 6-11, a second system and method 60 for transporting the solar panels 20 to a rooftop 12 of a facility for subsequent assembly into an array configuration is shown according to an exemplary embodiment. The second system and method 60 is shown to include a high density rack system 62 having a plurality of groups of staggered tracks 64, where each track pair 66 in each group 64 is configured to receive a solar panel 20. The staggered configuration of the tracks permits the pre-placement of standoffs 32 on one side of the solar panels 20 (shown as the front side of the rack 62 in FIG. 8), and on the opposite side of the bottom solar panel 20 in each group 64 (as shown on the back side of the rack 62 in FIG. 9).

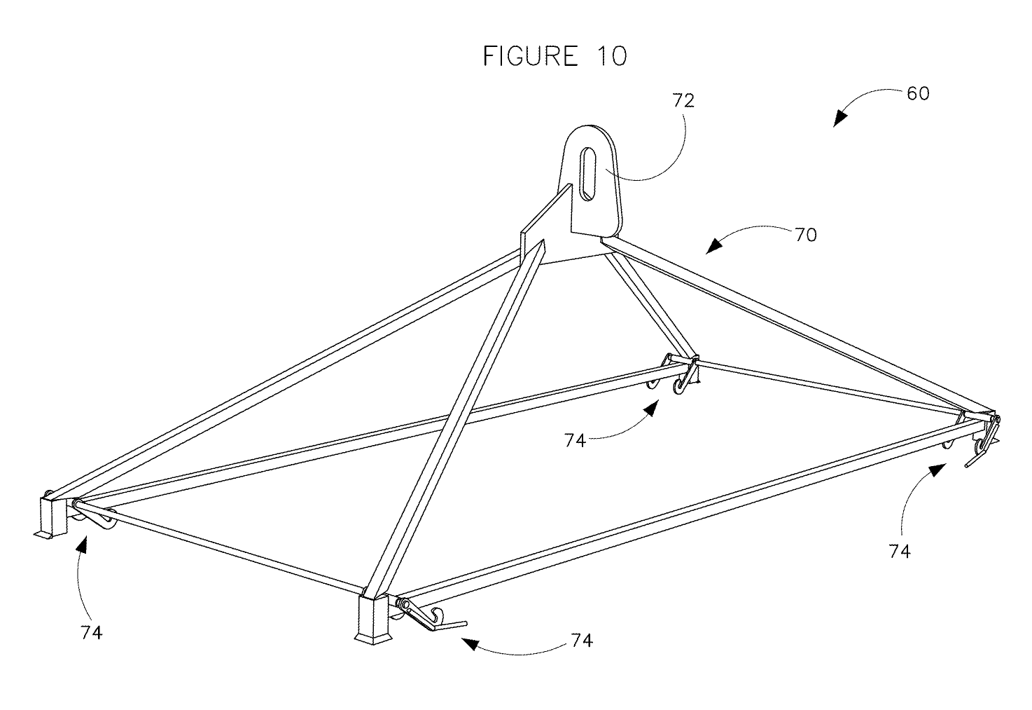

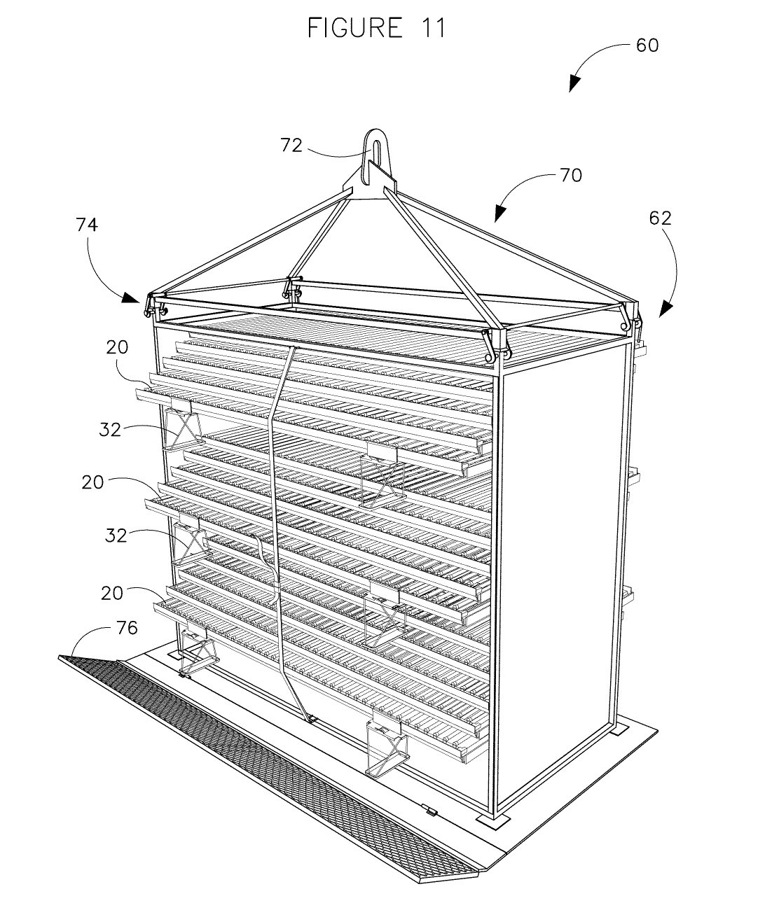

Referring further to FIGS. 10-11, the rack 62 is further shown to include a lifting apparatus 70 that is quickly and releasably coupled to a top portion of the rack 62, and includes a lift-eye 72 (or other suitable structure) for lifting the rack 62 using a suitable lifting device (such as a crane 14). According to one embodiment, at least two racks 62 are used during installation activities so that one rack 62 may be on the ground to facilitate loading of new solar panels 20 onto the groups 64 of staggered tracks 66 by a ground work crew, while another (full, loaded) rack 62 may be transported by the crane 14 to the rooftop 12 for unloading and installation by a rooftop work crew. The lifting apparatus 70 includes suitable latches 74 that engage corresponding structure on the top portion of the racks 62 to permit rotation of the racks 62 between ground and rooftop operations. The rack 62 is also shown to include a gate 76 which is movable between a closed position, and an open position (shown by way of example in FIG. 11) where it also serves as a standing platform for use by workers.

According to one embodiment of the disclosure, the second method 60 of transporting solar panels 20 to a rooftop 12 of a facility for subsequent assembly into an array, includes (among possible others) the steps of: providing a rack 62 having a plurality of parallel tracks 66, each of the parallel tracks 66 arranged in a progressively staggered configuration, so that at least one of the solar panels 20 is receivable on each of the parallel tracks 66; coupling at least one downwardly extending standoff 32 on one side of each of the solar panels 20; lifting the rack 62 and positioning the rack 62 onto the rooftop 12; removing the solar panels 20 from the rack 62; and assembling the solar panels 20 into an array at an inwardly-disposed location on the rooftop.

Together, the first and second system and method 30 and 60 are intended to provide a fast, convenient, efficient, and thus lower cost system and method for installing solar panels 20 in any desired pattern and at any desired location on the rooftop 12 of a facility.

Referring further to FIGS. 12-13, a connection system for assembling the solar panels 20 into an array (in both the first and second system and method 30 and 60) is shown according to an exemplary embodiment to include mechanical connectors and electrical connectors. The mechanical connectors 34 are shown as stainless steel spring clips that are configured to resiliently snap-fit over two frame members of adjacent solar panels 20. The connectors 34 are configured for use on the panels 20 in both a side-to-side manner and an end-to-end manner, so that the panels 20 can be quickly assembled (or disassembled). The connection system also includes suitable modular DC electrical connectors 36 (e.g. plugs and sockets, etc.) that may be quickly and simply assembled to one another in the desired circuit configuration, without the need for a qualified electrician.

According to either (or both) systems and methods 30 and 60 for installing solar panels 20 and a rooftop 12 location of a facility, a combined method of deploying a peripheral array of solar panels and a non-peripheral array of solar panes includes (among possible other) steps: installing a first group of solar panels 20 that have been preassembled into a first array on a rooftop 12 proximate a peripheral location according to the following sub-steps: providing a primary beam member 42 having a plurality of transverse receptacles 44; coupling a plurality of transverse rails 46 to the transverse receptacles 44; movably supporting a plurality of panel supports 48 having a hook portion 52 from the transverse rails 46; engaging the hook portion 52 of the panel supports 48 with each corner of the solar panels 20 in the preassembled array; and lifting the preassembled array of solar panels 20 and positioning the array onto the rooftop at a location proximate a perimeter of the facility. The combined method of deploying a peripheral array of solar panels 20 and a non-peripheral array of solar panels 20 also includes (among possible other) steps: transporting a second group of solar panels 20 to an inward location on the rooftop 12 that is inwardly disposed from the peripheral location (i.e. non-peripheral), and assembling the second group of solar panels 20 into a second array, according to the following sub-steps: providing a rack 62 having a plurality of parallel tracks 66, each of the parallel tracks 66 arranged in a progressively staggered configuration, so that at least one of the solar panels 20 is receivable on each of the parallel tracks 66; coupling at least one downwardly extending standoff 32 on one side of each of the solar panels 20; and lifting the rack 62 and positioning the rack 62 onto the rooftop; removing the solar panels 20 from the rack 62; and assembling the solar panels 20 into an array at the inward location on the rooftop 12.

According to any preferred embodiment, systems and methods for installing solar panels on a rooftop provide a fast, convenient, efficient, lower cost system and method for installing the solar panels in any desired pattern and at any desired location on the rooftop of a facility. One system and method installs solar panels in a preassembled array configuration on a rooftop (typically along perimeter locations on the rooftop), and another system and method transports the solar panels in a high density rack configuration to the rooftop (e.g. typically to more inwardly-disposed locations on the rooftop) for subsequent assembly into an array configuration on the rooftop.

As utilized herein, the terms “approximately,” “about,” “substantially,” and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the subject matter as recited in the appended claims.

It should be noted that the term “exemplary” as used herein to describe various embodiments is intended to indicate that such embodiments are possible examples, representations, and/or illustrations of possible embodiments (and such term is not intended to connote that such embodiments are necessarily extraordinary or superlative examples).

The terms “coupled,” “connected,” and the like as used herein mean the joining of two members directly or indirectly to one another. Such joining may be stationary (e.g., permanent) or moveable (e.g., removable or releasable). Such joining may be achieved with the two members or the two members and any additional intermediate members being integrally formed as a single unitary body with one another or with the two members or the two members and any additional intermediate members being attached to one another.

It should be noted that the orientation of various elements may differ according to other exemplary embodiments, and that such variations are intended to be encompassed by the present disclosure.

It is also important to note that the construction and arrangement of the systems and methods for installing solar panels as shown in the various exemplary embodiments is illustrative only. Although only a few embodiments have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter disclosed herein. For example, elements shown as integrally formed may be constructed of multiple parts or elements, the position of elements may be reversed or otherwise varied, and the nature or number of discrete elements or positions may be altered or varied. Accordingly, all such modifications are intended to be included within the scope of the present disclosure as defined in the appended claims. The order or sequence of any process or method steps may be varied or re-sequenced according to alternative embodiments. Other substitutions, modifications, changes and omissions may be made in the design, operating conditions and arrangement of the various exemplary embodiments without departing from the scope of the disclosure.

What is claimed is:

1. A system for installing a preassembled array of solar panels on a rooftop of a facility, comprising:
a primary beam member having a plurality of transverse receptacles;
a plurality of transverse rails engaged with the transverse receptacles;
a plurality of panel supports, each having a hook portion, and movably supported by the transverse rails, so that each of the solar panels in the preassembled array is supported by at least one of the panel supports.

2. The system of claim 1 wherein the solar panels in the preassembled array are mechanically interconnected to one another by spring-clip connectors.

3. The system of claim 1 wherein the solar panels in the preassembled array are electrically interconnected by modular quick-connect electrical connectors.

4. The system of claim 1 wherein primary beam member and the transverse rails and the panel supports are assembled into a substantially symmetric and balanced arrangement to define a lifting apparatus configured to transport the solar panels to a peripheral location on the rooftop.

5. The system of claim 4 wherein the lifting apparatus is adjustable to accommodate a plurality of different number of solar panels in the preassembled array.

6. A system for transporting a plurality of solar panels to a rooftop of a facility for subsequent assembly into an array, comprising:
a high-density rack having one or more pairs of staggered track groups, each pair of staggered track groups having a plurality of parallel tracks, each of the parallel tracks arranged in a progressively staggered configuration, so that one of the solar panels is receivable on each of the parallel tracks, and one side of the solar panels is capable of having at least one downwardly extending standoff coupled thereto.

7. The system of claim 6 further comprising a lifting apparatus having one or more latches releasably engagable with the high-density rack, and configured to permit lifting of the high-density rack to the rooftop of the facility.

8. The system of claim 6 wherein the high-density rack further comprises a gate movable between a closed position configured to contain the solar panels within the parallel tracks, and an open position configured to provide a support for workers.

9. The system of claim 6 wherein the pairs of staggered track groups and the parallel tracks are arranged substantially horizontally so that the solar panels are configured to be installed in, and removed from, the high-density rack in a substantially horizontal position.

10. A method of installing an array of solar panels on a rooftop of a facility, comprising the steps of:
providing a primary beam member having a plurality of transverse receptacles;
coupling a plurality of transverse rails to the transverse receptacles;
movably supporting a plurality of panel supports having a hook portion from the transverse rails;
engaging the hook portion of the panel supports with the solar panels in the preassembled array; and
lifting the preassembled array of solar panels and positioning the array onto the rooftop at a location proximate a perimeter of the facility.

11. The method of claim 10 wherein the panels supports are positioned so that one panel support corresponds to each corner of each of the solar panels.

12. The method of claim 10 further comprising the step of mechanically interconnecting the solar panels with a plurality of spring-clip connectors.

13. The method of claim 12 further comprising the step of electrically interconnecting the solar panels with a plurality of quick-connect electrical connectors.

14. The method of claim 10 wherein the array of solar panels are preassembled at a location that is separate from the rooftop, but generally adjacent to the facility.

15. A method of transporting solar panels to a rooftop of a facility for subsequent assembly into an array, comprising the steps of:
providing a first rack having a plurality of parallel tracks, each of the parallel tracks arranged in a progressively staggered configuration, so that at least one of the solar panels is receivable on each of the parallel tracks;
loading a first supply of the solar panels onto the parallel tracks;
coupling at least one downwardly extending standoff on one side of each of the solar panels; and
lifting the first rack and positioning the rack onto the rooftop;
unloading the first supply of the solar panels from the first rack; and
assembling the solar panels into an array at an inwardly-disposed location on the rooftop.

16. The method of claim 15, further comprising the step of providing a second rack that is substantially similar to the first rack, and loading a second supply of the solar panels onto the second rack, while unloading the first supply of the solar panels from the first rack.

17. A method of installing solar panels on a rooftop of a facility, comprising the steps of:
installing a first group of solar panels that have been preassembled into a first array on a rooftop proximate a peripheral location according to the following sub-steps:
providing a primary beam member having a plurality of transverse receptacles;
coupling a plurality of transverse rails to the transverse receptacles;
movably supporting a plurality of panel supports having a hook portion from the transverse rails;
engaging the hook portion of the panel supports with the solar panels in the preassembled array; and
lifting the preassembled array of solar panels and positioning the array onto the rooftop at a location proximate a perimeter of the facility;
transporting a second group of solar panels to an inward location on the rooftop that is inwardly disposed from the peripheral location, and assembling the second group of solar panels into a second array, according to the following sub-steps:
providing a rack having a plurality of parallel tracks, each of the parallel tracks arranged in a progressively staggered configuration, so that at least one of the solar panels is receivable on each of the parallel tracks;
coupling at least one downwardly extending standoff on one side of each of the solar panels; and
lifting the rack and positioning the rack onto the rooftop;
removing the solar panels from the rack; and
assembling the solar panels into an array at the inward location on the rooftop.

18. The method of claim 17 wherein the first group of solar panels that have been preassembled into the first array are mechanically interconnected by a plurality of spring-clip connectors, and are electrically interconnected using a plurality of quick-connect electrical connectors.

19. A method for minimally-invasive installation of solar panels on a rooftop of a facility, comprising:
assembling a plurality of solar panels into a preassembled array at a first location separate from the rooftop;
mechanically and electrically interconnecting the solar panels in the array at the first location;
coupling a lifting apparatus to the preassembled array;
aerially transporting the preassembled array from the first location to a second location disposed on the rooftop; and
electrically connecting the preassembled array to an electrical circuit for the facility.

20. The method of claim 19 wherein the lifting apparatus is adjustable to accommodate an array having a plurality of different numbers of solar panels, and includes at least a primary beam, and a plurality of transverse rails coupled to the primary beam, and a plurality of panel supports movably disposed on the transverse rails and having a lower portion engageable with the solar panels.
